(19) United States
(12) Patent Application Publication
(10) Pub. No.: US 2005/0181523 A1
(43) Pub. Date: Aug. 18, 2005

(54) Ferroelectric capacitor, method of manufacturing the same, and ferroelectric memory

(76) Inventor: Takeshi Kijima, Matsumoto-shi (JP)

Correspondence Address: HARNESS, DICKEY & PIERCE, P.L.C., P.O. BOX 828, BLOOMFIELD HILLS, MI, 48303, US

(21) Appl. No.: 11/056,033

(22) Filed: Feb. 11, 2005

(30) Foreign Application Priority Data
Feb. 12, 2004 (JP) 2004-034597

(51) Int. Cl. H01L 21/00; H01L 21/8242; H01L 31/062; H01L 29/76; H01L 31/113; H01L 29/94; H01L 31/119

(52) U.S. Cl. 438/3; 438/240

(57) ABSTRACT

A method of manufacturing a ferroelectric capacitor is provided capable of reducing manufacturing damages. In the method of manufacturing a ferroelectric capacitor, by sequentially depositing a lower electrode, a ferroelectric film, and an upper electrode on a substrate, dielectric films are formed, and then an ion beam is irradiated onto predetermined regions of the dielectric films, or ions of a predetermined element are injected onto the regions. Then, the regions where the ion beam is irradiated or the ions are injected onto are transformed into conductors, and thus it is possible to form the lower electrode and/or the upper electrode without etching.

### RELATED APPLICATIONS

This application claims priority to Japanese Patent Application No. 2004-034597 filed Feb. 12, 2004 which is hereby expressly incorporated by reference herein in its entirety.

### BACKGROUND

1. Technical Field

The present invention relates to a ferroelectric capacitor, a method of manufacturing the same, and a ferroelectric memory.

2. Related Art

In ferroelectric memories (FeRAMs), a ferroelectric is generally used to form capacitors, and data is held by the spontaneous polarization of the capacitors. Further, the capacitor is patterned to have a desired shape by a dry etching process.

However, since the etching process damages the materials used for manufacturing capacitor electrodes or ferroelectric films during the manufacturing process, the etching process often has adverse effects on the characteristics of the capacitors.

The present invention is designed to solve the above-mentioned problem, and it is an object of the present invention to provide a method of manufacturing a ferroelectric capacitor capable of reducing manufacturing damages. In addition, it is another object of the present invention to provide a ferroelectric capacitor having good characteristics with a minimum manufacturing damages and a ferroelectric memory having the ferroelectric capacitor.

### SUMMARY

(1) In order to achieve the above objects, the present invention provides a method of manufacturing a ferroelectric capacitor by sequentially depositing a lower electrode, a ferroelectric film, and an upper electrode on a substrate. The method comprises a step of forming a dielectric film; and a step of irradiating an ion beam onto a predetermined region of the dielectric film, or injecting ions of a predetermined element onto the predetermined region to transform the region into an electric conductor, thereby forming the lower electrode and/or the upper electrode.

According to the present invention, when forming the electrodes of the capacitor, first, the dielectric film is formed, and then only the predetermined region is transformed into an electric conductor, thereby forming the lower electrode or the upper electrode. Transforming the dielectric film into an electric conductor is realized by irradiating an ion beam or by injecting ions of a predetermined element. That is, in the present invention, it is possible to transform only a predetermined region of the dielectric film into an electric conductor to form a ferroelectric capacitor having a desired pattern without etching, and thus it is possible to reduce the manufacturing damages to members constituting the capacitor.

(2) In the manufacturing method of the present invention, the dielectric film may be formed of diamond-like carbon (DLC), and the ion beam may be irradiated onto a predetermined region of the dielectric film to transform the region into an electric conductor, thereby forming the lower electrode and/or the upper electrode.

The diamond-like carbon (DLC) is a carbon compound having an amorphous structure including SP3 bonding of carbon similar to a natural diamond, SP2 bonding of carbon similar to graphite, and bonding with hydrogen. The DLC is a low-permittivity (εr=˜2) dielectric having high hardness, low abrasion, low friction, and excellent surface flatness. When high energy such as an ion beam is applied to the DLC, the bonding thereof is broken, resulting in that the DLC is transformed into an electric conductor having low resistance. That is, according to this aspect, it is possible to form the lower electrode or the upper electrode having a desired pattern without etching, by irradiating an ion beam onto a predetermined region of the DLC film.

(3) In the manufacturing method of the present invention, the dielectric film may be formed of diamond-like carbon (DLC), and fluorine ions may be injected onto a predetermined region of the dielectric film to transform the region into an electric conductor, thereby forming the lower electrode and/or the upper electrode. DLC have low resistance by the adding of fluorine ions, and thus it can be used as an electric conductor. That is, according to this aspect, it is possible to form the lower electrode or the upper electrode having a desired pattern without etching, by injecting the fluorine ions onto a predetermined region of the DLC film.

(4) The present invention provides a method of manufacturing a ferroelectric capacitor by sequentially depositing a lower electrode, a ferroelectric film, and an upper electrode on a substrate. The method comprises a step of forming an electric conductor film; and a step of injecting ions of a predetermined element onto a predetermined region of the electric conductor film to transform the region into a dielectric, thereby forming the lower electrode and/or the upper electrode.

According to the present invention, when forming the electrodes of the capacitor, first, the electric conductor film is formed, and then only the predetermined region is transformed into a dielectric, thereby forming the lower electrode or the upper electrode. Transforming the electric conductor film into a dielectric is realized by injecting ions of a predetermined element. That is, in the present invention, it is possible to transform only a predetermined region of the electric conductor film into a dielectric to form a ferroelectric capacitor having a desired pattern without etching, and thus it is possible to reduce the manufacturing damages to members constituting the capacitor.

(5) In the manufacturing method of the present invention, an electric conductor film may be formed of a fluorine compound containing diamond-like carbon (DLC), and nitrogen ions may be injected onto a predetermined region of the electric conductor film to transform the region into a dielectric, thereby forming the lower electrode and/or the upper electrode. The fluorine compound containing DLC is an electric conductor, but it is also possible to use the electric conductor as a dielectric by adding nitrogen ions to the fluorine compound. That is, according to this aspect, it is possible to form the lower electrode or the upper electrode having a desired pattern without etching, by injecting nitrogen ions onto a predetermined region of the fluorine compound film containing the DLC.

(6) In the manufacturing method of the present invention, the electric conductor film may be formed of In_{2-X}Sn_{X}O₃ (ITO), and antimony ions may be injected onto a predetermined region of the electric conductor film to transform the region into a dielectric, thereby forming the lower electrode and/or the upper electrode. The ITO is obtained by doping tin (Sn) into an indium oxide (In₂O₃), and the tin is located at a substitution position of indium to form In_{2-X}Sn_{X}O₃. The ITO is an electric conductor, but the electric conductor can be used as a dielectric by adding antimony (Sn) to the ITO. In addition, since ITO has excellent heat resistance and lattice matching with a PZT-based ferroelectric, ITO is a material suitable for a capacitor electrode. That is, according to this aspect, it is possible to form the lower electrode or the upper electrode having a desired pattern without etching, by injecting antimony ions onto a predetermined region of an ITO film.

(7) The present invention provides a ferroelectric capacitor manufactured by the method according to any one of the above-mentioned aspects.

(8) The present invention provides a ferroelectric memory comprising the ferroelectric capacitor.

### BRIEF DESCRIPTION OF THE DRAWINGS

FIG. 1 is cross-sectional views illustrating processes of manufacturing a first ferroelectric capacitor according to an embodiment of the present invention.

FIG. 2 is cross-sectional views illustrating processes of manufacturing a second ferroelectric capacitor according to another embodiment of the present invention.

FIG. 3 is a plan view and a cross-sectional view respectively illustrating a ferroelectric memory according to the embodiment of the present invention.

FIG. 4 is flow diagrams illustrating a process of manufacturing a memory cell array of the ferroelectric memory according to the embodiment of the present invention.

FIG. 5 is a flow diagram illustrating the process of manufacturing the memory cell array of the ferroelectric memory according to the embodiment of the present invention.

FIG. 6 is a flow diagram illustrating the process of manufacturing the memory cell array of the ferroelectric memory according to the embodiment of the present invention.

FIG. 7 is a flow diagram illustrating the process of manufacturing the memory cell array of the ferroelectric memory according to the embodiment of the present invention.

FIG. 8 is a flow diagram illustrating the process of manufacturing the memory cell array of the ferroelectric memory according to the embodiment of the present invention.

### DETAILED DESCRIPTION

Hereinafter, preferred embodiments of the present invention will be described with reference to the accompanying drawings.

1. Method of Manufacturing a First Ferroelectric Capacitor

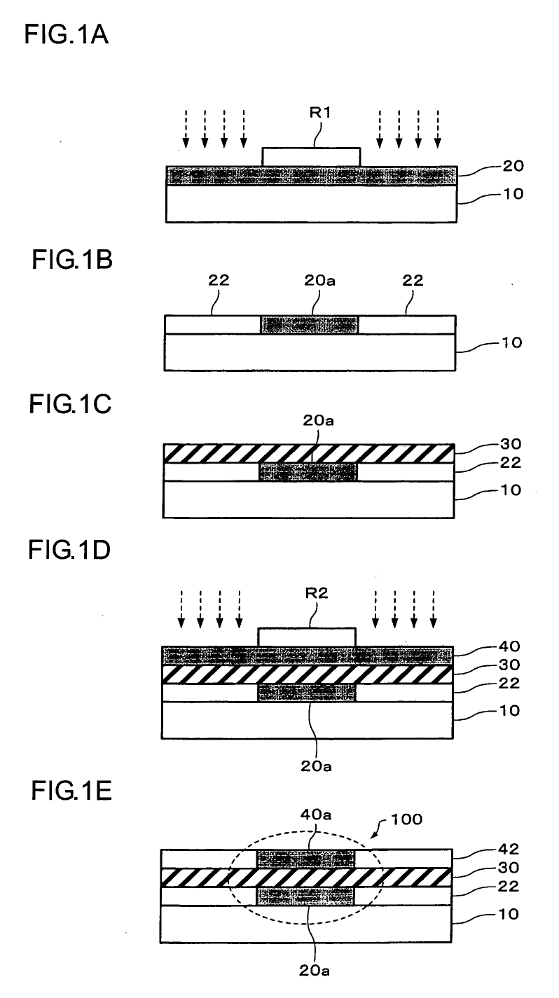

FIGS. 1(A) to 1(E) are cross-sectional views schematically illustrating processes for manufacturing the first ferroelectric capacitor according to an embodiment of the present invention.

In the method of manufacturing the first ferroelectric capacitor according to the present embodiment, first, a lower electrode 20a is formed on a substrate 10 (see FIGS. 1(A) and 1(B)). For example, a semiconductor substrate made of silicon or an SOI substrate can be used as the substrate 10. The lower electrode 20a is composed of an electric conductor film 20 made of a conductive oxide called In_{2-X}Sn_{X}O₃ (ITO) or a fluorine compound (DLCF) containing diamond-like carbon (DLC). The conductor film 20 is formed by various film forming methods, such as a CVD method, a spray pyrolysis method, a vacuum evaporation method, an electron-beam evaporation method, a sputtering method, an ion-beam sputtering method, an ion plating method, and an ion assist evaporation method, etc.

A method of forming the lower electrode 20a will be described below in more detail. First, the electric conductor film 20 is formed on the substrate 10, and a resist R1 is formed on a portion of the electric conductor film 20 where the lower electrode 20a will be formed. Subsequently, ions of a predetermined element are injected onto the electric conductor film 20. For example, in case of DLCF, nitrogen (N) ions are injected thereonto, and in case of ITO, antimony (Sb) ions are injected thereonto. By this, the ion-injected region becomes a dielectric (specific resistance is changed to 1×10⁶ Ωcm). In this way, it is possible to obtain the lower electrode 20a having a desired pattern without etching. In addition, the resist R1 is removed after the ion injection is completed.

Next, a ferroelectric film 30 is formed on the lower electrode 20a (see FIG. 1(C)). The ferroelectric film 30 is made of a perovskite-type ferroelectric material, such as PZT or PZTN obtained by adding Nb to PZT, or a perovskite-type ferroelectric material having a Bi layer shape, such as SBT or BIT. The film is formed by a solution applying method, a sputtering method, a CVD method, etc.

Then, an upper electrode 40a is formed on the ferroelectric film 30 (see FIGS. 1(D) and 1(E)). More specifically, similar to the case of the lower electrode 20a, an electric conductor film 40 is formed, and then a resist R2 is formed on a portion of the electric conductor film 40 opposite to the lower electrode 20a. Subsequently, ions of a predetermined element are injected onto the electric conductor film 40, similar to the case for forming the lower electrode 20a, such that a region of the electric conductor film 40 that is not covered with the resist R2 is transformed into a dielectric. In this way, it is possible to obtain the upper electrode 40a having a desired pattern without etching. In the method of manufacturing the first ferroelectric capacitor, it is possible to obtain a ferroelectric capacitor 100 in the above-mentioned way.

As described above, according to the present embodiment, it is possible to manufacture the ferroelectric capacitor 100 including the lower electrode 20a and the upper electrode 40a having desired patterns by transforming specific regions of the dielectric films 20 and 40 into dielectrics without etching process. Therefore, it is possible to reduce manufacturing damages to members constituting a capacitor.

2. Method of Manufacturing a Second Ferroelectric Capacitor

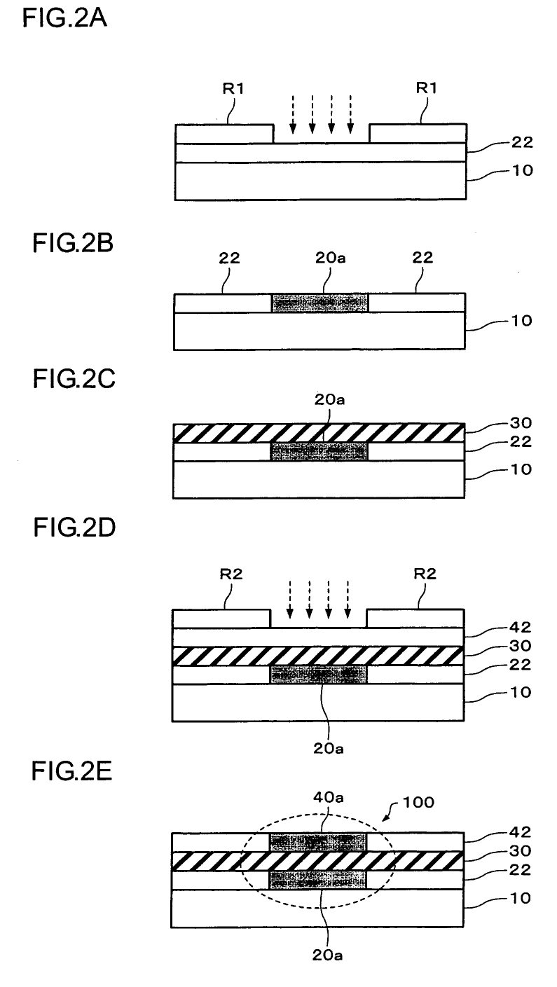

FIGS. 2(A) to 2(E) are cross-sectional views schematically illustrating processes for manufacturing the second ferroelectric capacitor according to another embodiment of the present invention. In FIGS. 2(A) to 2(E), members having substantially the same functions as those in FIGS. 1(A) to 1(E) have the same reference numerals, and a detailed description thereof will be omitted for the simplicity of explanation.

In the method of manufacturing the second ferroelectric capacitor according to the present embodiment, first, the lower electrode 20a is formed on the substrate 10 (see FIGS. 2(A) and 2(B)). The lower electrode 20a is composed of an electric conductor film 20 made of a fluorine compound (DLCF) containing diamond-like carbon (DLC) or carbon (C). The electric conductor film 20 is formed by various film forming methods, such as a CVD method, a spray pyrolysis method, a vacuum evaporation method, an electron-beam evaporation method, a sputtering method, an ion-beam sputtering method, an ion plating method, and an ion assist evaporation method, etc.

A method of forming the lower electrode 20a according to the present embodiment will be described below in more detail. First, a dielectric film 22 made of the diamond-like carbon (DLC) is formed on the substrate 10, and a resist R1 is formed on the dielectric film 22 in order that a region where the lower electrode 20a will be formed is exposed. Subsequently, ions of a predetermined element which is fluorine (F) are injected onto the dielectric film 22, so that the ion-injected region becomes a conductor having low resistance (below 10⁻² Ωcm). In this way, it is possible to obtain the lower electrode 20a having a desired pattern without etching. In addition, the resist R1 is removed after the ion injection is completed. Further, when high energy such as an ion beam is irradiated to DLC, the bonding of DLC is broken and is transformed into a low-resistance (6×10⁻³ Ωcm) conductor made of carbon (C). Therefore, according to the present embodiment, instead of injecting ions onto the dielectric film 22 made of DLC, energy such as an ion beam is irradiated onto the dielectric film 22 to transform it to a conductor. In this case, since the dielectric film 22 can be directly manufactured by the ion beam process without a masking process using a resist, it is possible to omit a resist applying process, which results in a decrease in the number of processes. Further, the specific resistance of DLC is about 10⁹ Ωcm, which is much larger than that of carbon. Thus, when transforming DLC into a conductor by irradiating an ion beam, it is possible to obtain a large difference in conductivity between the electric conductor film 20 and the dielectric film 22.

Next, the ferroelectric film 30 is formed on the lower electrode 22a (see FIG. 2(C)), and the upper electrode 40a is formed on the ferroelectric film 30 (see FIGS. 2(D) and 2(E)). More specifically, similar to the case of the lower electrode 20a, a dielectric film 42 is formed, and then a resist R2 is formed on the dielectric film 42 in order that a portion of the dielectric film 42 opposite to the lower electrode 20a is exposed. Subsequently, ions of a predetermined element which is fluorine are injected onto the dielectric film 42, or an ion beam is irradiated onto the dielectric film 42 to transform a region of the dielectric film 40 that is not covered with the resist R2 into an electric conductor. In this way, it is possible to obtain the upper electrode 40a having a desired pattern without etching. In the method of manufacturing the second ferroelectric capacitor, it is possible to obtain a ferroelectric capacitor 100 in the above-mentioned way.

As described above, according to the present embodiment, it is possible to form the ferroelectric capacitor 100 including the lower electrode 20a and the upper electrode 40a having desired patterns by transforming specific regions of the dielectric films 22 and 42 into electric conductors without etching process. Therefore, it is possible to reduce manufacturing damages to members constituting a capacitor.

3. Method of Manufacturing a Ferroelectric Memory and a Ferroelectric Memory Cell Array

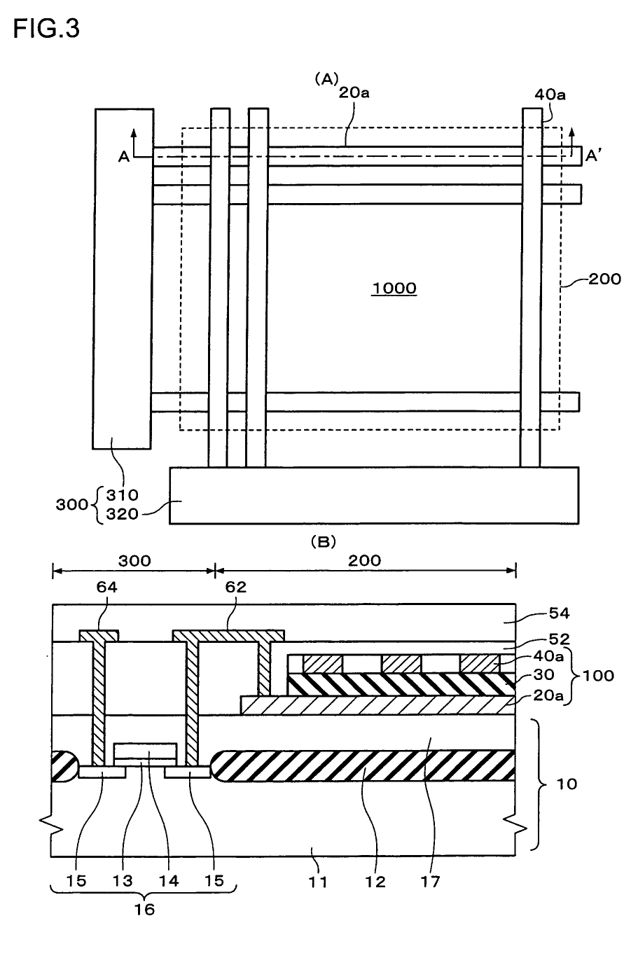

FIGS. 3(A) and 3(B) are views schematically illustrating a ferroelectric memory 1000 having a memory cell array using the ferroelectric capacitor obtained by the above-mentioned methods. Further, FIG. 3(A) is a plan view of the ferroelectric memory 1000, and FIG. 3(B) is a cross-sectional view taken along the line A-A′ of FIG. 3(A).

As shown in FIG. 3(A), the ferroelectric memory 1000 includes a memory cell array 200 and a peripheral circuit unit 300. The memory cell array 200 and the peripheral circuit unit 300 are formed in different layers. In addition, the peripheral circuit unit 300 and the memory cell array 200 are arranged in different areas on a semiconductor substrate 11. Further, the examples of the peripheral circuit unit 300 may include a Y gate, a sense amplifier, an input/output buffer, an X address decoder, a Y address decoder, or an address buffer.

In the memory cell array 200, the lower electrodes 20a (word lines) for row selection are arranged to intersect the upper electrodes 40a (bit lines) for column selection. In addition, the lower electrodes 20a and the upper electrodes 40a have a plurality of stripe-shaped signal electrodes. Further, the signal electrodes can be formed such that the lower electrodes are the bit lines and the upper electrodes 40a are the word lines. Since the lower electrodes 20a and the upper electrodes 40a are formed using the method according to the above-mentioned embodiment, they sustain little manufacturing damages.

As shown in FIG. 3(B), the ferroelectric film 30 is arranged between the lower electrodes 20a and the upper electrodes 40a. In the memory cell array 200, the ferroelectric capacitors 100 serving as memory cells are formed in regions where the lower electrodes 20a intersect the upper electrodes 40a. In addition, the ferroelectric film 30 may be arranged between the regions where the lower electrodes 20a intersect the upper electrodes 40a.

Further, in the ferroelectric memory 1000, a second interlayer insulating film 52 is formed to cover the lower electrodes 20a, the ferroelectric film 30, and the upper electrodes 40a. In addition, an insulating protective film 54 is formed on the second interlayer insulating film 52 so as to cover wiring layers 62 and 64.

As shown in FIG. 3(A), the peripheral circuit unit 200 includes various circuits for selectively writing/reading information on/from the memory cell 200. That is, the peripheral circuit unit 200 includes a first driving circuit 310 for selectively controlling the lower electrodes 20a, a second driving circuit 320 for selectively controlling the upper electrodes 40a, a signal detecting circuit (not shown) such as a sense amplifier, and the like.

Furthermore, as shown in FIG. 3(B), the peripheral circuit unit 300 includes MOS transistors 16 formed on the semiconductor substrate 10. Each MOS transistor 16 has a gate insulating film 13, a gate electrode 14, and a source/drain region 15. The respective MOS transistors 16 are separated from each other by an element separating region 12. A first interlayer insulating film 17 is formed on the semiconductor substrate 10 having the MOS transistors 16 thereon. In addition, the peripheral circuit unit 300 and the memory cell array 200 are electrically connected to each other by the wiring layer 62.

Next, writing and reading operations in the ferroelectric memory 1000 will be described below.

First, in the reading operation, a reading voltage is applied to a capacitor in the selected memory cell, which is also an operation of writing ‘0’ thereon. In this case, a current passing through a selected bit line or a voltage when a bit line has high impedance is read from the sense amplifier. Then, a predetermined voltage is applied to capacitors in non-selected memory cells to prevent crosstalk at the time of reading.

In the reading operation, when ‘1’ is written, a writing voltage to invert a polarized state is applied to a capacitor in the selected memory cell. When ‘0’ is written, a writing voltage not to invert the polarized state is applied to a capacitor in the selected memory cell to hold the ‘0’ state written at the time of the reading operation. In this case, a predetermined voltage is applied to capacitors in non-selected memory cells to prevent crosstalk at the time of writing.

According to the ferroelectric memory 1000, the ferroelectric capacitor 100 is formed by the above-mentioned manufacturing method without etching process. Therefore, it is possible to improve product quality and yield.

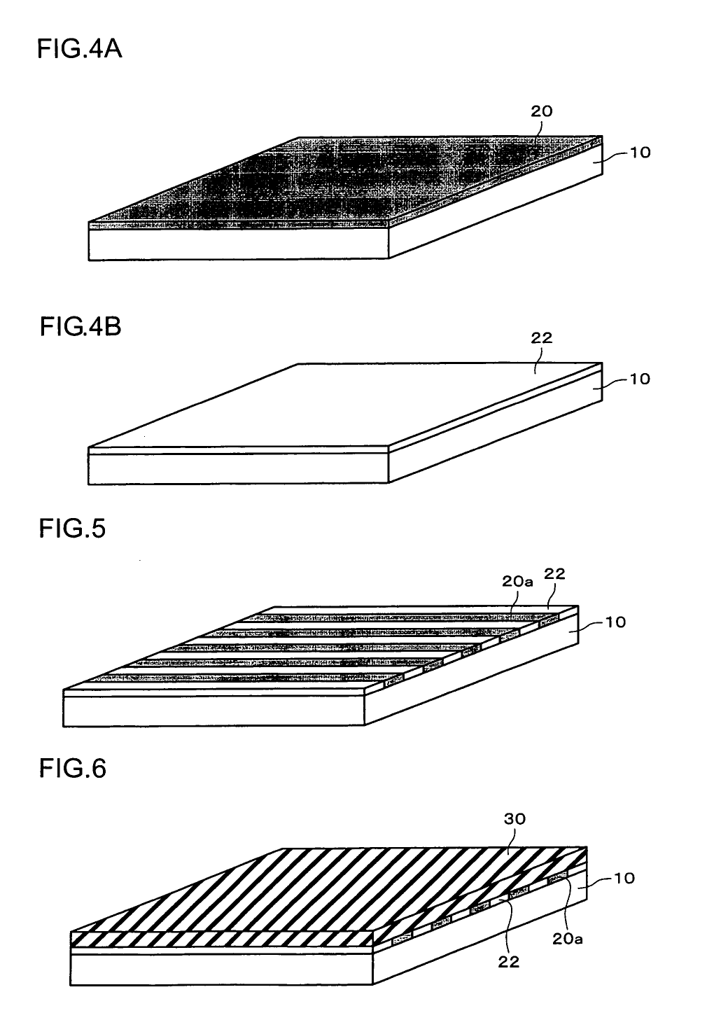

Next, a method of manufacturing the memory cell array 200 applying the ferroelectric capacitor manufacturing method according to the present embodiment will be described with reference to FIGS. 4 to 8.

First, the conductor film 20 or the dielectric film 22 is formed on the substrate 10 (see FIGS. 4(A) and 4(B)). Then, according to the processes illustrated in FIGS. 1(A) and 1(B) or FIGS. 2(A) and 2(B), a resist is formed on the conductor film 20 or the dielectric film 22 in a stripe pattern, and ion injection or ion-beam irradiation is performed on the conductor film 20 or the dielectric film 22, thereby forming the lower electrode 20a having the stripe pattern (see FIG. 5).

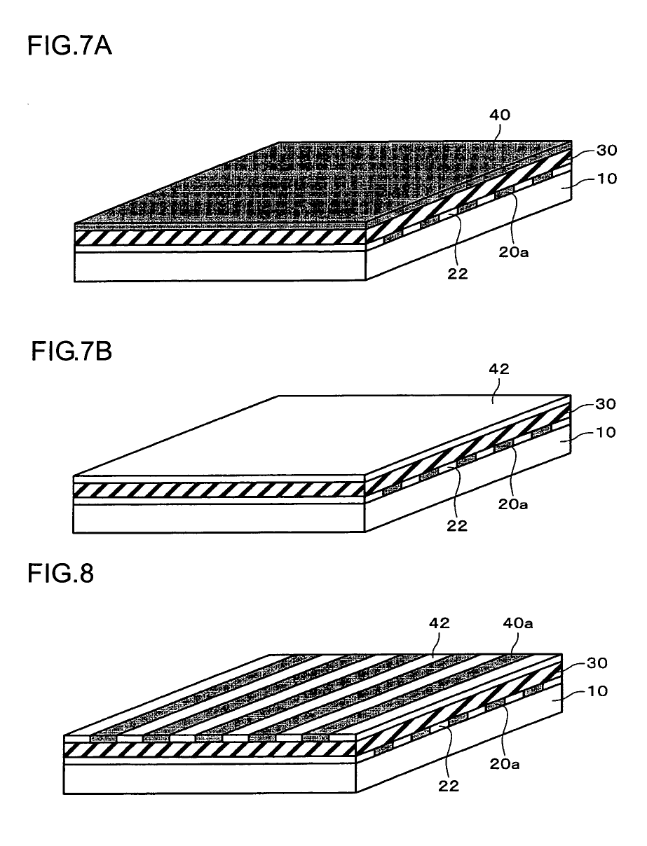

Then, the ferroelectric film 30 is formed to cover the lower electrode 20a (see FIG. 6), and the conductor film 40 or the dielectric film 42 is formed on the ferroelectric film 30, similar to the case of the lower electrode 20a (see FIGS. 7(A) and 7(B). Finally, according to the processes illustrated in FIGS. 1(D) and 1(E) or FIGS. 2(D) and 2(E), a resist is formed on the conductor film 40 or the dielectric film 42 in a stripe pattern so as to intersect the lower electrode 20a, and ion injection or ion-beam irradiation is performed on the conductor film 40 or the dielectric film 42, thereby forming the upper electrode 40a intersecting the lower electrode 20a. In this way, it is possible to obtain the memory cell array 200.

As described above, when applying the first or second ferroelectric capacitor manufacturing method according to the present embodiments to a simple matrix-type (cross point type) memory in which the density between electrodes shown in FIGS. 3(A) to 3(B) is high, it is possible to form the lower electrode 20a and the upper electrode 40a without etching process. As a result, it is possible to obtain a high-quality memory cell array 200 with little manufacturing damages. In addition, even when the distance between electrodes is short as in the ferroelectric memory 1000 according to the present embodiment, it is possible to suppress parasitic capacitance by using low-permittivity DLC (including DLCN) as a dielectric film when forming the lower electrode 20a and the upper electrode 40a.

Although the preferred embodiments of the present invention are described above, the present invention is not limited to the above-mentioned embodiments. That is, various modifications and changes can be made within the scope and sprit of the present invention.

1. A method of manufacturing a ferroelectric capacitor by sequentially depositing a lower electrode, a ferroelectric film, and an upper electrode on a substrate, the method comprising:
a step of forming a dielectric film; and
at least one of:
a step of irradiating an ion beam onto a predetermined region of the dielectric film; and
a step of injecting ions of a predetermined element onto the predetermined region to transform the region into an electric conductor;
thereby forming at least one of the lower electrode and the upper electrode.

2. The method of manufacturing a ferroelectric capacitor according to claim 1, wherein:
the dielectric film is formed of diamond-like carbon (DLC); and
the ion beam is irradiated onto a predetermined region of the dielectric film to transform the region into an electric conductor, thereby forming the lower electrode and/or the upper electrode.

3. The method of manufacturing a ferroelectric capacitor according to claim 1, wherein:
the dielectric film is formed of diamond-like carbon (DLC); and
fluorine ions are injected onto a predetermined region of the dielectric film to transform the region into an electric conductor, thereby forming the at least one of the lower electrode and the upper electrode.

4. A method of manufacturing a ferroelectric capacitor by sequentially depositing a lower electrode, a ferroelectric film, and an upper electrode on a substrate, the method comprising:
a step of forming an electric conductor film; and
a step of injecting ions of a predetermined element onto a predetermined region of the electric conductor film to transform the region into a dielectric, thereby forming the lower electrode and/or the upper electrode.

5. The method of manufacturing a ferroelectric capacitor according to claim 4, wherein:
the electric conductor film is formed of a fluorine compound containing diamond-like carbon (DLC); and
nitrogen ions are injected onto a predetermined region of the electric conductor film to transform the region into a dielectric, thereby forming the lower electrode and/or the upper electrode.

6. The method of manufacturing a ferroelectric capacitor according to claim 4, wherein:
the electric conductor film is formed of In_{2-X}Sn_{X}O₃ (ITO); and
antimony ions are injected onto a predetermined region of the electric conductor film to transform the region into a dielectric, thereby forming the lower electrode and/or the upper electrode.

7. A ferroelectric capacitor manufactured by the method according to claim 1.

8. A ferroelectric memory comprising the ferroelectric capacitor according to claim 7.

9. A ferroelectric capacitor manufactured by the method according to claim 4.

10. A ferroelectric memory comprising the ferroelectric capacitor according to claim 9.
